(19) United States
(12) Patent Application Publication
(10) Pub. No.: US 2002/0142631 A1
(43) Pub. Date: Oct. 3, 2002

(54) Connecting assembly

(76) Inventor: Yung-Cheng Chang, Taoyuan Hsien (TW)

Correspondence Address: Niro, Scavone, Haller & Niro, 181 West Madison Street-Suite 4600, Chicago, IL, 60602-4515, US

(21) Appl. No.: 10/074,828

(22) Filed: Feb. 12, 2002

(30) Foreign Application Priority Data
Apr. 2, 2001 (TW) 90205083

(51) Int. Cl. H05K 1/00

(52) U.S. Cl. 439/78

(57) ABSTRACT

A connecting assembly is provided. The connecting assembly includes a first object having a first base, a second object having a second base electrically connected to the first object, at least one connecting pin having two ends respectively plugged in and electrically connected between the first base of the first object and the second base of the second object, and a sleeve having an interior space for mounting the at least one connecting pin, wherein the sleeve has a first slot and a second slot on its two ends which cover the first base of the first object and the second base of the second object, respectively.

### FIELD OF THE INVENTION

The present invention is related to a connecting assembly, and more particularly to a connecting assembly used in the connection between a first object and a second object.

### BACKGROUND OF THE INVENTION

Presently, the functions of and uses for the electronic apparatuses are increasingly promoted, so that the signal transmission within the interior of the electronic apparatuses is more and more complicated. Therefore, the desired signal transmission would not be easily achieved by a conventional single circuit board and should be performed by a plurality of circuit boards. Moreover, each of the plurality of circuit boards is electrically connected to each other, respectively, by at least one connecting pins for fixing the plurality of circuit boards to perform the desired signal transmission.

Please refer to FIGS. 1(a) and 1(b), which are schematic views showing a first conventional connecting assembly. The first conventional connecting assembly (not shown) includes two sleeves 10, a plurality of connecting pins 11, upper and lower circuit boards 13 and connecting sockets 131. Moreover, the plurality of connecting pins 11 are fixed by two sleeves 10 and two ends of the plurality of connecting pins 11 are respectively plugged in the connecting sockets 131 on the upper and lower circuit boards 13 in order to fix the circuit boards 13 and be electrically connected to each other. Nevertheless, the plurality of connecting pins 11 are very tiny, and the following two conditions will occur easily.

(1) When the plurality of connecting pins 11 are plugged in the two circuit boards 13, the plurality of connecting pins 11 are too difficult to be accurately plugged in a plurality of corresponding holes 1311 of the connecting sockets 131. If plugging by force, the breakage or crookedness in some of the plurality of connecting pins 11 will occur a contact fault in the connection between the two circuit boards 13. Furthermore, The contact fault and the difficulty in assembling will more easily occur when the circuit boards 13 are electrically connected by multiplex connecting assemblies, respectively. Therefore, the cost of checking and replacing unsuitable pins will be increased substantially.

(2) The plurality of connecting pins 11 merely include a smooth metal surface and the friction thereof is inadequate to maintain the connection between the plurality of connecting pins 11 and the plurality of corresponding holes 1311. Therefore, the connection is also broken down because of moving or shaking the connecting assembly even when the plurality of connecting pins 11 have been accurately plugged in the two circuit boards 13.

Please refer to FIG. 1(c), which is a schematic view showing a second conventional connecting assembly. The plurality of connecting pins 11 also are fixed by the two sleeves 10, but both sides of the plurality of connecting pins 11 include the extended connecting pins capable of guiding to be plugged in the connecting sockets (not shown). The second connecting assembly shown in FIG. 1(c) is more easily connected between two circuit boards (not shown) than the first connecting assembly shown in FIGS. 1(a) and 1(b). However, the problem of the friction of the plurality of connecting pins 11 is inadequate to maintain the connection between the two circuit boards still has not been solved.

It is therefore tried by the applicant to deal with the above situations encountered in the prior art.

### SUMMARY OF THE INVENTION

It is therefore an object of the present invention to provide a connecting assembly by applying a sleeve including two slots on two ends thereof so as to guide the sleeve to cover two bases on two objects.

It is another object of the present invention to provide the connecting assembly, in which the cost of checking, replacing and assembling the connecting assembly could be highly reduced.

It is another object of the present invention to provide the connecting assembly to tightly fix and protect the plurality of connecting pins from breakage or crookedness in the connection between the two objects.

According to an aspect of the present invention, there is provided a connecting assembly. The connecting assembly includes a first object having a first base, a second object electrically connected to the first object and having a second base, at least one connecting pin having two ends respectively plugged in and electrically connected between the first base of the first object and the second base of the second object, and a sleeve having an interior space for mounting the at least one connecting pin therein, wherein the sleeve has a first slot and a second slot on two ends thereof which cover the first base of the first object and the second base of the second object, respectively.

Preferably, the first object and the second object are printed circuit boards (PCB).

Preferably, the first slot and the second slot have inwardly tapered outlets for guiding the sleeve to cover the first base of the first object and the second base of the second object, respectively.

Preferably, the first base and the second base are connecting sockets.

According to another aspect of the present invention, there is provided a connecting assembly used in a connection between a first object having a first base and a second object having a second base, wherein the first object is electrically connected to the second object. The connecting assembly includes at least one connecting pin having two ends for being electrically connected with the first object and the second object, respectively, and a sleeve having an interior space for mounting the at least one connecting pin therein, wherein the sleeve has a first slot and a second slot on two ends thereof which cover the first base of the first object and the second base of the second object, respectively.

The present invention may best be understood through the following descriptions with reference to the accompanying drawings, in which:

### BRIEF DESCRIPTION OF THE DRAWINGS

FIGS. 1(a) and 1(b) are schematic views showing a first conventional connecting assembly;

FIG. 1(c) is a schematic view showing a second conventional connecting assembly;

FIGS. 2(a) and 2(b) are schematic views showing a connecting assembly according to a first preferred embodiment of the present invention; and

FIGS. 3(a) and 3(b) are schematic views showing a connecting assembly according to a second preferred embodiment of the present invention.

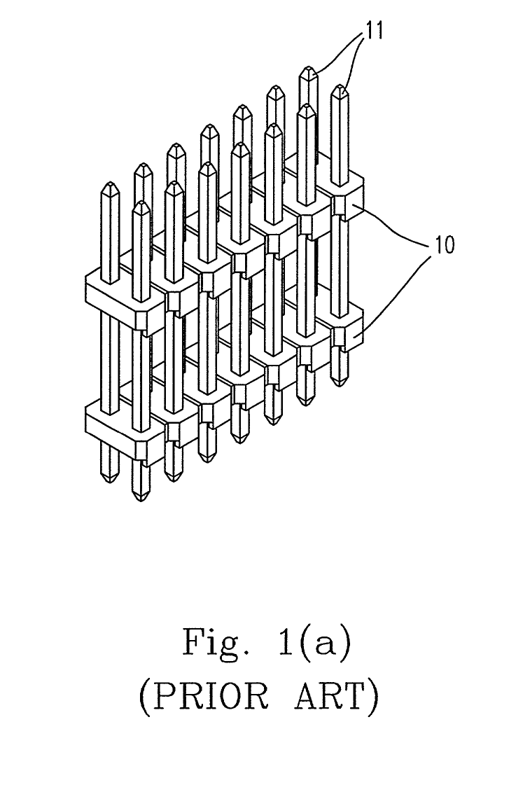

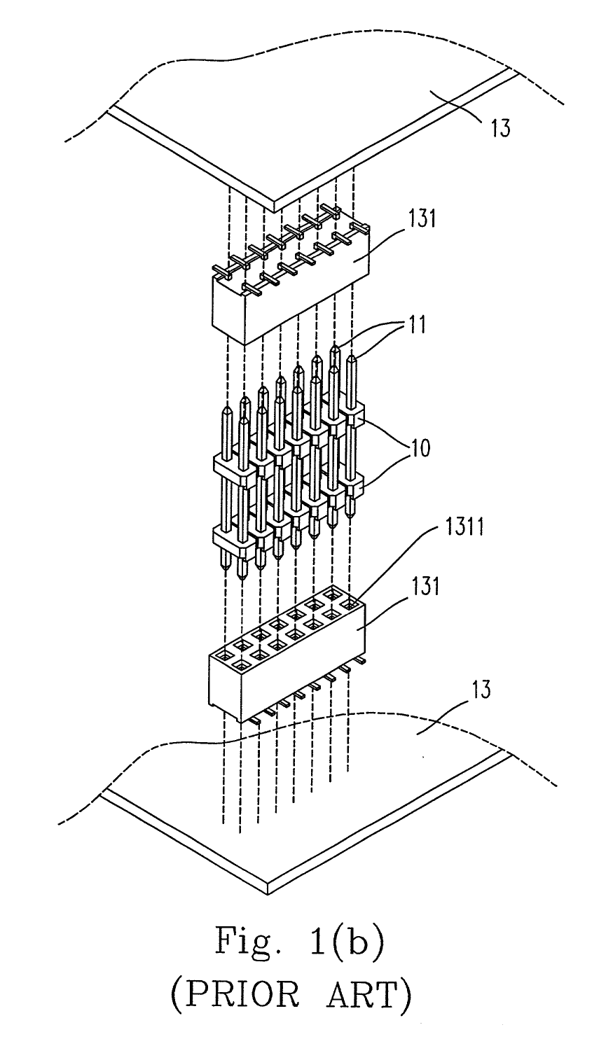

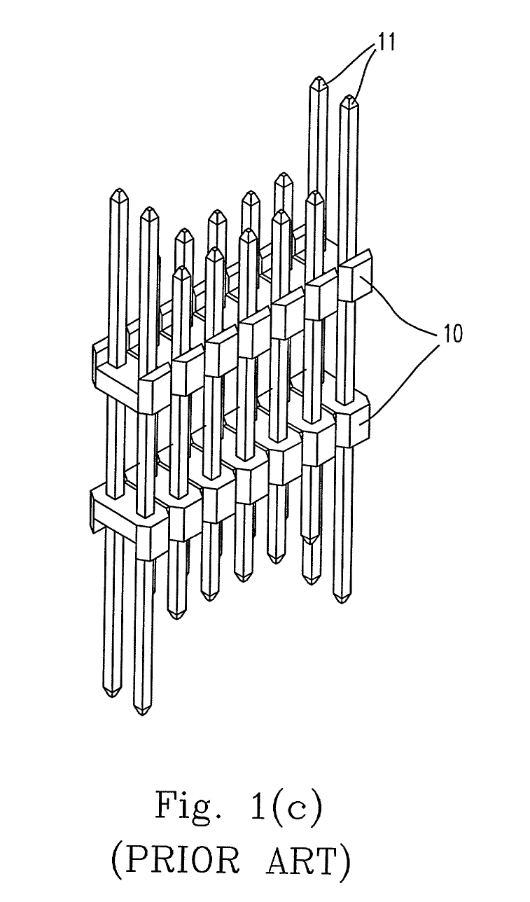

### DETAILED DESCRIPTION OF THE PREFERRED EMBODIMENT

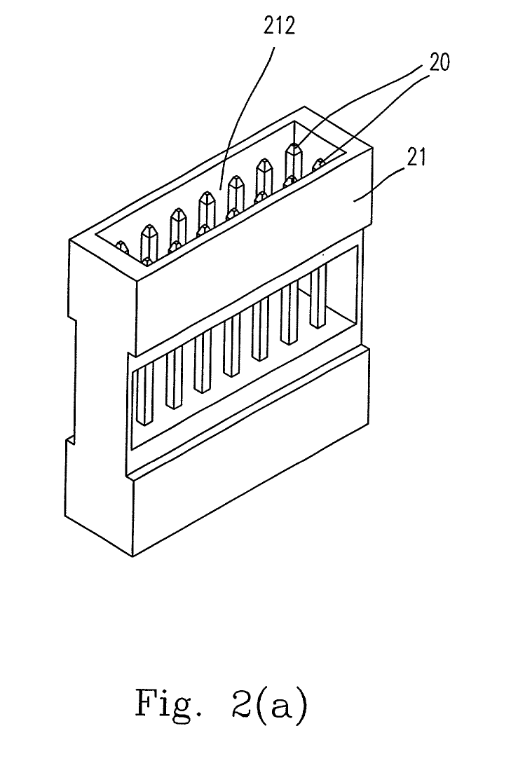

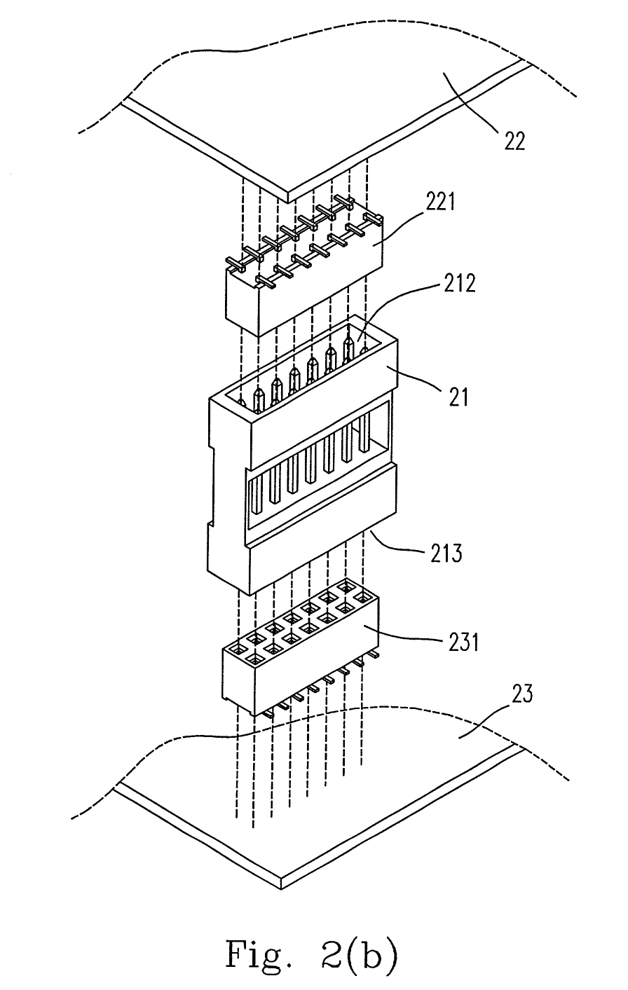

Please refer to FIGS. 2(a) and 2(b), which are schematic views showing a connecting assembly according to a first preferred embodiment of the present invention. The connecting assembly includes a first object 22 having a first base 221, a second object 23 having a second base 231, at least one connecting pin 20 and a sleeve 21. The second object 23 is electrically connected to the first object 22. The at least one connecting pin 20 having two ends are respectively plugged in and electrically connected between the first base 221 of the first object 22 and the second base 231 of the second object 23. The sleeve 21 has an interior space for mounting the at least one connecting pin 20 therein. Furthermore, the sleeve 21 has a first slot 212 and a second slot 213 on two ends thereof to cover the first base 221 of the first object 22 and the second base 231 of the second object 23, respectively. The first object 22 and the second object 23 are electronic objects and are preferably printed circuit boards (PCB). The first base 221 and the second base 231 are preferably connecting sockets.

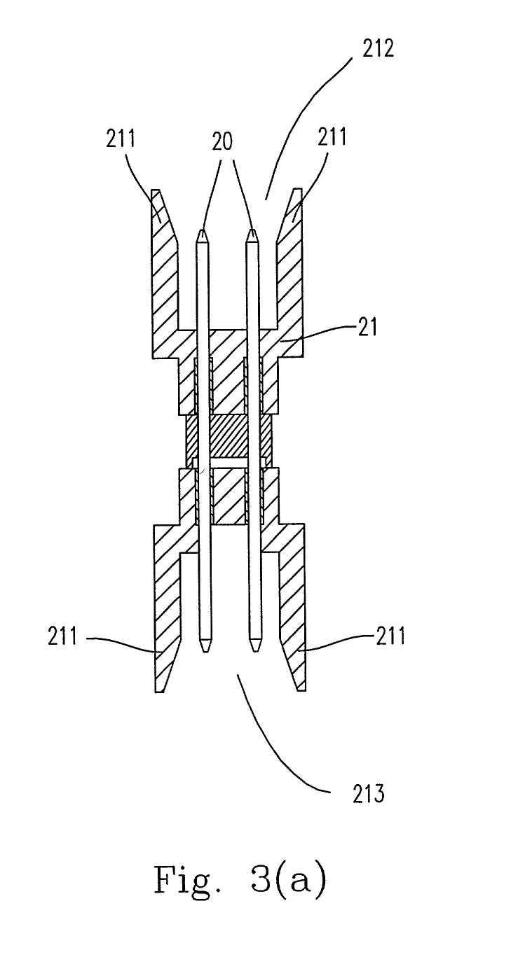

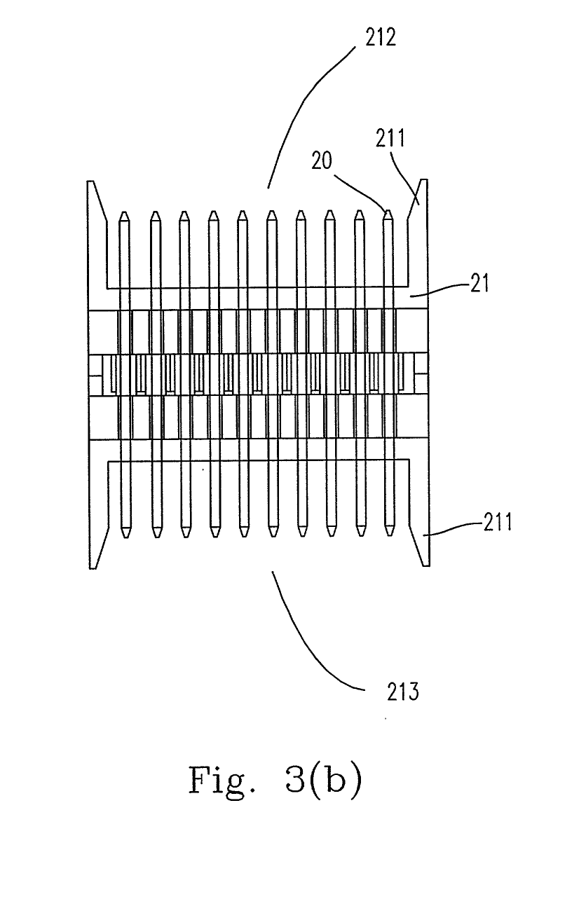

Please refer to FIGS. 3(a) and 3(b), which are schematic views showing a connecting assembly according to a second preferred embodiment of the present invention. The difference between the connecting assemblies respectively shown in FIGS. 3(a) and 3(b) and FIGS. 2(a) and 2(b) is that the first slot 212 and the second slot 213 have inwardly tapered outlets 213 for guiding the sleeve 21 to cover the first base (not shown) of the first object (not shown) and the second base (not shown) of the second object (not shown), respectively. Therefore, the accuracy and the convenience in the assemblage and the connection between the first object and the second object will be promoted.

It is to be understood that the connecting assembly according to the present invention will tightly fix and protect the plurality of connecting pins from breakage or crookedness. The drawback of the breakage or the crookedness in the plurality of connecting pins of the connection between the two objects in the prior art could be effectively overcome according to the present invention. Furthermore, the connecting assembly includes an inwardly tapered outlet of the slot so as to guiding the sleeve to efficiently cover the object. Therefore, the cost of checking, replacing and assembling in the present connecting assembly could be highly reduced.

While the invention has been described in terms of what are presently considered to be the most practical and preferred embodiments, it is to be understood that the invention need not be limited to the disclosed embodiment. On the contrary, it is intended to cover various modifications and similar arrangements included within the spirit and scope of the appended claims which are to be accorded with the broadest interpretation so as to encompass all such modifications and similar structures. Therefore, the above description and illustration should not be taken as limiting the scope of the present invention which is defined by the appended claims.

What is claimed is:

1. An connecting assembly, comprising:
a first object having a first base;
a second object electrically connected to said first object and having a second base;
at least one connecting pin having two ends respectively plugged in and electrically connected between said first base of said first object and said second base of said second object,; and
a sleeve having an interior space for mounting said at least one connecting pin therein, wherein said sleeve has a first slot and a second slot on two end thereof which cover said first base of said first object and said second base of said second object, respectively.

2. The connecting assembly according to claim 1, wherein said first object and said second object are printed circuit boards (PCB).

3. The connecting assembly according to claim 1, wherein said first slot and second slot have inwardly tapered outlets for guiding said sleeve to cover said first base of said first object and said second base of said second object, respectively.

4. The connecting assembly according to claim 1, wherein said first base and said second base are sockets.

5. A connecting assembly used in a connection between a first object having a first base and a second object having a second base, wherein said first object is electrically connected to said second object, comprising:
at least one connecting pin having two ends for being electrically connected with said first object and said second object, respectively; and
a sleeve having an interior space for mounting said at least one connecting pin therein, wherein said sleeve has a first slot and a second slot on two end thereof which cover said first base of said first object and said second base of said second object, respectively.
